(19) United States
(12) Patent Application Publication
(10) Pub. No.: US 2025/0244426 A1
(43) Pub. Date: Jul. 31, 2025

(54) Determining Magnetic Resonance Coil Sensitivity Data

(71) Applicant: Siemens Healthineers AG, Forchheim (DE)

(72) Inventors: Mario Zeller, Erlangen (DE); Flavio Carinci, Würzburg (DE)

(73) Assignee: Siemens Healthineers AG, Forchheim (DE)

(21) Appl. No.: 19/041,083

(22) Filed: Jan. 30, 2025

(30) Foreign Application Priority Data
Jan. 31, 2024 (DE) 10 2024 200 897.4

(51) Int. Cl. G01R 33/48; G01R 33/483; G01R 33/56; G01R 33/561

(52) U.S. Cl. CPC G01R 33/4818; G01R 33/4835; G01R 33/5608; G01R 33/5611

(57) ABSTRACT

Techniques are provided to determine magnetic resonance coil sensitivity data. This includes acquiring reference data of individual slices via a coil comprising at least two antenna elements and one coil channel per antenna element, the acquired reference data fully sampling the k-space at least in a central region of the k-space. The techniques further include loading at least undersampled data set acquired via the coil, and determining a supplementary kernel for at least one loaded set of data acquired via the coil based upon the acquired reference data. The techniques also include determining, at least in a central region of the k-space, reconstructed reference data that is fully sampled from the loaded sets of data acquired by means of the coil using the determined supplementary kernels, and determining coil sensitivity data of the coil on the basis of the reconstructed reference data.

### CROSS-REFERENCE TO RELATED APPLICATIONS

The present application claims priority to and the benefit of Germany patent application no. DE 10 2024 200 897.4 filed on Jan. 31, 2024, the contents of which are incorporated herein by reference in their entirety.

### TECHNICAL FIELD

The disclosure relates to an improved method for determining magnetic resonance coil sensitivity data.

### BACKGROUND

Magnetic resonance (MR) technology is a well-known modality by means of which images of the inside of an examination subject can be generated. In simple terms, the examination subject is positioned for this purpose in a magnetic resonance device in a comparatively strong, static, homogeneous basic magnetic field, also known as the B0 field, at field strengths of 0.2 tesla to 7 tesla and more, such that its nuclear spins align themselves along the basic magnetic field. In order to trigger nuclear spin resonances that are measurable as signals, radiofrequency (RF) excitation pulses are radiated into the examination subject, the triggered nuclear spin resonances are measured as data known as k-space data by means of coils configured for receiving signals, and MR images are reconstructed or spectroscopic data is determined on the basis thereof. The alternating magnetic field generated by the excitation pulses broadcast by means of a transmit coil is also referred to as the B1 field. For spatially encoding the measurement data, rapidly switched magnetic gradient fields, known as gradients, are superimposed on the basic magnetic field. A scheme used that describes a temporal sequence of RF pulses to be transmitted, and gradients to be switched, is referred to as a pulse sequence (scheme), or also as a sequence for short. The recorded measurement data is then digitized and stored as complex numeric values in a k-space matrix. An associated MR image can be reconstructed from the k-space matrix populated with values e.g. by means of a multidimensional Fourier transform.

In this case, there are essentially two ways of generating echo signals following an excitation of the nuclear spins. On the one hand, the excited nuclear spins can be manipulated by switching dephasing and rephasing gradients in such a way that the signal decays more rapidly than is due to the T2* decay inherent in the measured tissue, but after a certain time, the echo time (TE), following the RF excitation pulse used there is formed what is termed a gradient echo (GRE) that is to be measured. Sequences of said type are generally referred to as GRE sequences.

On the other hand, a sequence known as a spin echo (SE) can also be generated by application of at least one RF refocusing pulse after the application of an RF excitation pulse after a time, again referred to as the echo time, following the RF excitation pulse, which spin echo SE is measured and its amplitude, though, is reduced in accordance with the T2 decay inherent in the measured tissue. Sequences of said type are generally referred to as SE sequences.

In each case, the excitation and the measurement of the generated echo signals in each sequence are repeated as necessary (e.g. with switching of different gradients for spatial encoding purposes) until the desired number of echo signals has been measured and stored in the k-space to enable the examination subject to be imaged.

### SUMMARY

Among the SE sequences, e.g. the TSE sequences (TSE: Turbo Spin Echo), which are also known by the names FSE (Fast Spin Echo) or RARE (Rapid Acquisition with Refocused Echoes) sequences, are widely established in clinical applications. The advantage of the TSE sequences compared to the “simple” SE sequence is that, after an RF excitation pulse, a plurality of refocusing pulses are switched and, consequently, a plurality of spin echo signals are also generated. This results in faster data acquisition.

With so-called “single shot” methods, the totality of k-space data that is to be acquired in this case, e.g. to image a slice to be imaged of an examination subject, can be collected after just one RF excitation by means of an RF excitation pulse.

An example of such a “single-shot” TSE sequence is the HASTE sequence (HASTE: Half-Fourier Acquisition Single-shot Turbo spin Echo imaging), in which a “partial Fourier” method, e.g. the half-Fourier method, is employed in addition to reduce the amount of k-space data that is to be acquired. In this case, the symmetry of the k-space with respect to complex conjugation is used to derive non-measured k-space data from the measured k-space data. This enables all of the k-space data of a slice to be imaged that is required for the method to be acquired after just one excitation pulse. If it is intended to measure slices of an examination subject, e.g. all the required k-space data of a slice can be acquired by means of HASTE after just one excitation. For this reason, HASTE techniques are typically employed for acquiring images of the thorax or abdomen, as they permit relatively large volumes of interest (VOIs) to be covered within one or more breath-hold phases with a reduced sensitivity toward physiological movements of the examination subject.

HASTE acquisition techniques are also known, inter alia, by the acronyms SS-FSE (Single-Shot Fast Spin Echo), SSH-TSE (Single-SHot Turbo Spin Echo), UFSE (Ultra-Fast Spin Echo), Single-Shot Fast SE, FASE, or Super-FASE (Fast Advanced Spin Echo).

Also known in addition to the cited partial-Fourier methods are methods referred to as parallel acquisition techniques (e.g. GRAPPA (GeneRalized Autocalibrating Partially Parallel Acquisition) and SENSE (SENSitivity Encoding), with the aid of which acquisition times required for acquiring the desired data can be shortened, and which are therefore also referred to as acceleration techniques. As in the case of partial-Fourier methods, only parts of the echo signals that are actually to be acquired according to the Nyquist condition are measured as k-space data in this case. In contrast to the partial-Fourier methods, however, in the case of parallel acquisition techniques the non-measured parts are generally more uniformly distributed over the k-space that is to be measured according to Nyquist, such that e.g. only every second k-space line is measured.

With parallel acquisition techniques, the “missing” k-space data is further reconstructed with the aid of coil sensitivity data that characterizes the coils used for measuring the measurement data, which coils in this case consist of a plurality of antenna elements, each having an associated coil channel. Said coil sensitivity data of the coils used for the acquisition of the measurement data is determined from reference data, which samples at least an area of the k-space that is to be measured, in most cases the central region, completely according to the Nyquist condition, and may also be referred to as sensitivity maps of the respective coils. The coil sensitivity data determined from the reference measurement data for a reconstruction of missing k-space data is specific to the respective undersampling of the measurement data specifying the “missing”, and therefore to be added, k-space data and in this context is also referred to as a supplementary kernel, or “kernel” for short (in the case of GRAPPA also as a “GRAPPA kernel”).

The desire for ever faster MR scans in the clinical environment is currently leading to a renaissance of further acceleration techniques, e.g. of methods in which multiple images are acquired simultaneously. Generally, these methods can be characterized in that at least during a part of the measurement a targeted transverse magnetization of at least two slices is applied simultaneously for the imaging process (“multislice imaging”, “slice multiplexing”). In contrast thereto, with the established “multislice imaging” method, the signals of at least two slices are acquired alternately, i.e. totally independently of one another with a correspondingly longer measurement time.

Examples of known methods for this purpose include the technique known as Hadamard encoding, methods using simultaneous echo refocusing, methods using broadband data acquisition, or also methods employing parallel imaging in the slice direction. The last-cited methods also include for example the CAIPIRINHA technique, as described by Breuer et al. in “Controlled Aliasing in Parallel Imaging Results in Higher Acceleration (CAIPIRINHA) for Multi-Slice Imaging”, Magnetic Resonance in Medicine 53, 2005, pp. 684-691, and the blipped CAIPIRINHA technique, as described by Setsompop et al. in “Blipped-Controlled Aliasing in Parallel Imaging for Simultaneous Multislice Echo Planar Imaging With Reduced g-Factor Penalty”, Magnetic Resonance in Medicine 67, 2012, pp. 1210-1224.

In particular, in the case of the last-cited slice multiplexing methods, a pulse called a multiband RF pulse is used to excite or otherwise manipulate, e.g. to refocus or saturate, two or more slices concurrently (simultaneously). Such a multiband RF pulse is in this case e.g. a multiplex of individual RF pulses, which would be used to manipulate the individual slices that are to be manipulated simultaneously. As a result of the multiplexing, e.g. a baseband-modulated multiband RF pulse is obtained from an addition of the pulse shapes of the individual RF pulses. In this case, the spatial encoding of the acquired signals is substantially achieved by an established gradient switching in two directions (two-dimensional gradient encoding). In terms of its effect, the multiband RF pulse is spatially selectively limited to the desired slices.

The resulting signals are acquired by means of a plurality of receive antennas from all the excited slices collapsed in a dataset, and then separated according to the individual slices with the aid of parallel acquisition techniques.

As already mentioned hereinabove, parallel acquisition techniques can already be employed generally to shorten the acquisition time required for acquiring the desired data by means of an incomplete acquisition according to Nyquist, i.e. an undersampling of the k-space.

In slice multiplexing methods, parallel acquisition techniques are used to separate the measurement data acquired simultaneously for different slices once more with the aid of coil sensitivity data of the coils used. In this process, it is necessary to acquire reference data for all the affected slices. This usually happens in the course of a reference measurement, which is to be performed in addition, and which measures reference data individually for each desired slice, from which reference data coil sensitivity data can be determined.

A further acceleration technique is one known as compressed sensing, in which the k-space is likewise undersampled, though in this case with a maximally (pseudo-) random distribution of the measured k-space points. Compressed sensing (CS) is described in more detail e.g. in Lustig et al. “Sparse MRI: The application of compressed sensing for rapid MR imaging”, Magnetic Resonance in Medicine: An Official Journal of the International Society for Magnetic Resonance in Medicine 58.6 (2007): 1182-1195, or also in Lustig et al. “Compressed sensing MRI”, IEEE Signal Processing Magazine 25.2 (2008): pp. 72-82. Herein, data relating to non-measured k-space points, i.e. the “missing” measurement data, is determined by means of iterative reconstruction functions with the addition of a priori knowledge, which are included as boundary conditions in the optimization problem of the reconstruction function, and may likewise comprise coil sensitivity data.

For some years now, it has further been known to apply trained reconstruction functions comprising neural networks based on so-called deep learning (DL) algorithms to reconstruct image data from undersampled measurement data acquired by means of magnetic resonance technology. Coil sensitivity data is also used within the scope of such trained reconstruction functions, e.g. to ensure data consistency.

An overview of the principles of parallel acquisition techniques, CS, and associated iterative reconstruction functions through to trained reconstruction functions is given in the article by Knoll et al., “Deep-Learning Methods for Parallel Magnetic Resonance Imaging Reconstruction: A Survey of the Current Approaches, Trends, and Issues”, IEEE Signal Processing Mag. 37(1): pp.128-140 (2020).

For the cited techniques, which employ coil sensitivity data in the reconstruction of image data from the measured measurement data, the accuracy and quality of the coil sensitivity data used are critical for a successful image reconstruction. Interference factors, e.g. due to movement or pulsation during an acquisition of reference data, on the basis of which coil sensitivity data is determined, can therefore lead to artifacts in image data reconstructed using the thus determined coil sensitivity data. Measurements that utilize a TSE sequence for the acquisition of the measurement data for the imaging and separate reference measurements for the acquisition of the reference data are particularly susceptible. With such measurements, e.g. initially for all N slices that are to be acquired, fully sampled reference data is acquired within a few seconds (e.g. by means of HASTE reference measurements). This is normally followed by the acquisition of the measurement data for the imaging, the measurement data being acquired using accelerated means, i.e. by undersampling. For example, parts (e.g. k-space lines) of the k-space are acquired in m echo trains for all N slices in each case. If, during this process, reference data was acquired while an interference occurred, e.g. in a phase of pulsatile flow, then in most cases large parts of the k-space where reference data has been acquired are contaminated by the interference. As a result of the distributed acquisition of the measurement data for the imaging over multiple time periods, only individual k-space trajectories, e.g. individual k-space lines, are affected there in many cases.

The object underlying the present disclosure is to enable an improved determination of coil sensitivity data that reduces a contamination of the reference data by interference factors.

This object is achieved by the embodiments as discussed herein with respect to the method for determining magnetic resonance coil sensitivity data, a magnetic resonance system, a computer program, and an electronically readable data medium, including those embodiments described in further detail in the claims.

A method according to the disclosure for determining magnetic resonance coil sensitivity data comprises the steps:
acquiring reference data of individual slices by means of a coil comprising at least two antenna elements and one coil channel per antenna element, wherein the acquired reference data samples the k-space completely according to Nyquist at least in a central region of the k-space,
loading at least one set, undersampled according to Nyquist, of data acquired by means of the coil,
determining a supplementary kernel for at least one loaded set of data acquired by means of the coil on the basis of the acquired reference data,
determining, at least in a central region of the k-space, reconstructed reference data that is complete according to Nyquist from the loaded sets of data acquired by means of the coil using the determined supplementary kernels,
determining coil sensitivity data of the coil on the basis of the reconstructed reference data.

As a result of the inventive determination of reconstructed reference data on the basis of which the desired coil sensitivity data is determined, interference effects in acquired reference data can be relativized, thereby reducing a susceptibility to artifacts in image data reconstructed using the determined coil sensitivity data and thus increasing an achievable image quality.

By reconstructing the reconstructed reference data, which can be accomplished for example by means of a GRAPPA technique, interference effects, e.g. due to pulsations during the acquisition of the reference data, are reduced since the supplementary kernels are obtained by averaging over the entire k-space and consequently provide a globally optimal solution. A proportion of local sources of interference is reduced as a result. Moreover, further existing interference effects often have a different phase in the artificially generated k-spaces and consequently advantageously average one another out.

A magnetic resonance system according to the disclosure comprises a magnet unit, a gradient unit, a radiofrequency unit, and a control device embodied for performing a method according to the disclosure and having a reconstruction unit.

A computer program according to the disclosure implements a method according to the disclosure on a control device when the program is executed on the control device. For example, the computer program comprises commands which, when the program is executed by a control device, e.g. a control device of a magnetic resonance system, cause said control device to perform a method according to the disclosure. The control device may be embodied in the form of a computer.

In this case, the computer program may also be present in the form of a computer program product that can be loaded directly into a memory of a control device and has program code means to perform a method according to the disclosure when the computer program product is executed in a computing unit of the computing system.

A computer-readable storage medium according to the disclosure comprises commands that, when executed by a control device (e.g. a control device of a magnetic resonance system), cause said control device and/or magnetic resonance system to perform any of the methods according to the disclosure.

The computer-readable storage medium may be embodied as an electronically readable data medium on which electronically readable control information is stored which comprises at least one computer program according to the disclosure and is embodied in such a way that it performs a method according to the disclosure when the data medium is used in a control device of a magnetic resonance system.

The advantages and embodiments cited in relation to the method also apply analogously to the magnetic resonance system, the computer program product, and the electronically readable data medium.

### BRIEF DESCRIPTION OF THE DRAWINGS

Further advantages and details of the present disclosure will become apparent from the exemplary embodiments described in the following as well as with reference to the drawings. The examples presented do not imply any limitation of the disclosure. In the drawings:

FIG. 1 illustrates a schematic flowchart of an example method according to the disclosure for determining coil sensitivity data according to the disclosure;

FIG. 2 illustrates a schematic diagram of an example workflow for determining reconstructed reference data according to the disclosure;

FIG. 3 illustrates a schematic diagram of an example further workflow for determining reconstructed reference data according to the disclosure; and

FIG. 4 illustrates a schematic view of an example magnetic resonance system according to the disclosure.

### DETAILED DESCRIPTION OF THE DISCLOSURE

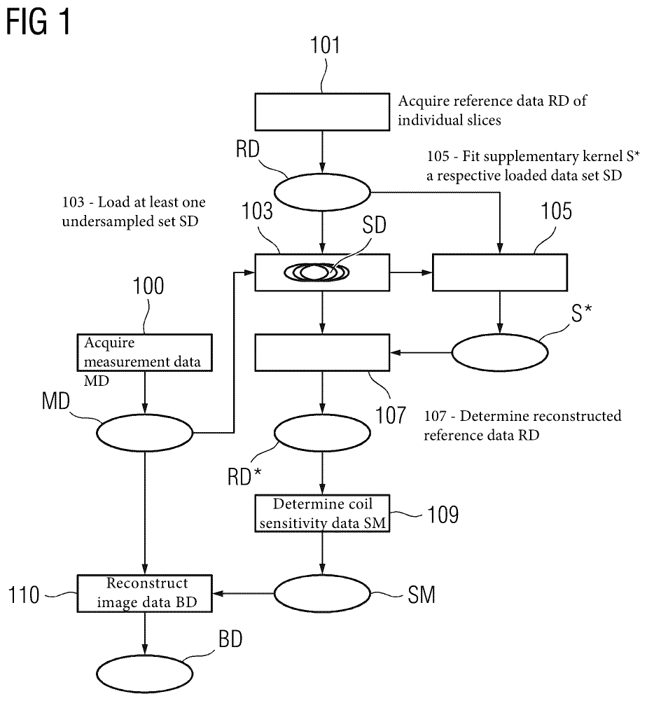

FIG. 1 illustrates a schematic flowchart of an example method according to the disclosure for determining coil sensitivity data SD according to the disclosure.

Reference data RD of individual slices is acquired by means of a coil comprising at least two antenna elements and one coil channel per antenna element (block 101), wherein the acquired reference data RD samples the k-space fully according to Nyquist (e.g. satisfying the known Nyquist condition) at least in a central region of the k-space. The reference data RD can be acquired using any suitable techniques, including conventional means, e.g. by means of separate HASTE reference measurements.

At least one set SD, undersampled according to Nyquist, of data acquired by means of the coil is loaded (block 103).

A supplementary kernel S* is determined on the basis of the acquired reference data RD for at least one loaded set SD of data acquired by means of the coil, which supplementary kernel is fitted to the respective undersampling of the loaded set SD of data acquired by means of the coil (block 105). This process can be carried out in any suitable manner, including the use of known processes.

Using the determined supplementary kernels S*, reconstructed reference data RD* that is complete according to Nyquist is determined at least in a central region of the k-space from the loaded sets SD of data acquired by means of the coil (block 107). By using the supplementary kernels S*, the determination of the reconstructed reference data RD* can supplement the incomplete loaded sets SD of data acquired by means of the coil to produce complete sets of data.

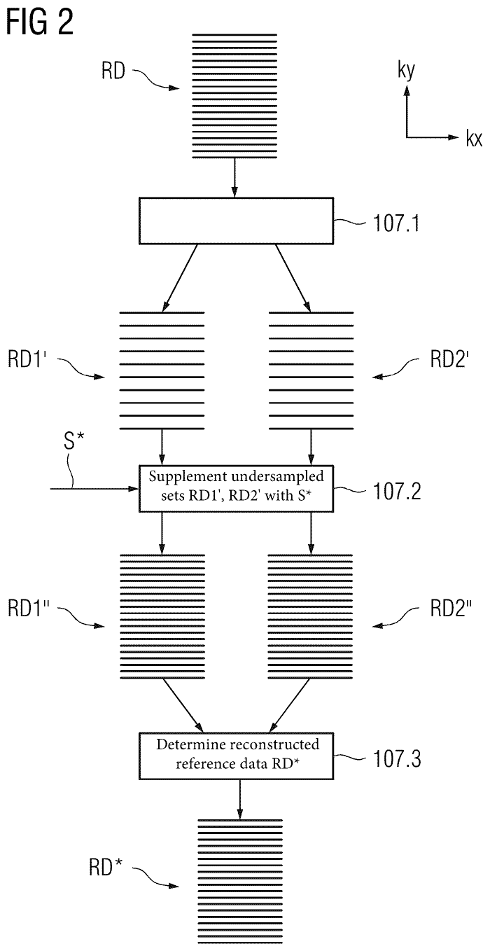

FIG. 2 illustrates a schematic diagram of an example workflow for determining reconstructed reference data RD* according to the disclosure. In the case shown, reference data RD acquired along k-space lines extending in the readout direction kx and spaced apart in the phase encoding direction ky is subdivided into two sets of undersampled reference data RD1′ and RD2′ (block 107.1), e.g. by allocating every second k-space line to the second undersampled set RD2′ of reference data, and the other k-space lines remain in a first, in that case also undersampled, set RD1′ of reference data.

A loaded set SD of data acquired by means of the coil can therefore have been determined on the basis of the acquired reference data RD. The reference data RD is data acquired by means of the desired coil and is available. The reference data RD is determined completely according to Nyquist in a central region of the k-space. In order to obtain undersampled sets SD of data acquired by means of the coil on the basis of the acquired reference data RD, the completely acquired reference data RD can be subdivided into sets of undersampled data, which are loaded as sets SD of data acquired by means of the coil. Generally, when the reference data RD has been acquired in k-space lines, n sets SD of acquired data can be generated by assigning every nth k-space line of the reference data RD to a set SD of acquired data.

At least one (or even all) of the undersampled sets RD1′ and RD2′ thus generated from the acquired reference data RD can in each case be supplemented using the associated supplementary kernels S* to produce sets of data RD1″ and RD2″, which are complete according to Nyquist (block 107.2), for example in accordance with a GRAPPA technique. If the acquired reference data RD has been subdivided into more than two sets of undersampled reference data RD1′, RD2′, an analogous procedure can be conducted.

If at least two sets SD of acquired data have been loaded, each of which has been supplemented using the associated supplementary kernels S* to produce sets of data RD1″, RD2″ that are complete according to Nyquist, the reconstructed reference data RD* can be determined on the basis of the at least two supplemented sets RD1″, RD2″ of data (block 107.3).

In this case, the determination of the reconstructed reference data RD* may for example comprise an averaging of supplemented sets RD1″, RD2″ of data.

It is also conceivable that the determination of the reconstructed reference data RD* comprises a discarding of non-supplemented data in the supplemented sets RD1″, RD2″ of data, with the result that no measured reference data is contained any longer in the reconstructed reference data RD* but the reconstructed reference data RD* consists purely of reconstructed data.

In addition or alternatively, the determination of the reconstructed reference data RD* may comprise a comparison of at least two supplemented sets RD1″ and RD2″ of data on the basis of which contaminated parts of the k-space of the supplemented sets RD1″, RD2″ of data can be identified and, if necessary, discarded. A comparison of said kind can be conducted e.g. by simple subtraction of the k-spaces of RD1″ and RD2″ and subsequent addition in the kx direction. This enables individual k-space lines that are severely affected by interference to be identified and discarded. Ideally, both k-spaces would namely be largely identical. The supplemented sets RD1″ and RD2″ of data generally comprise sufficient k-space lines such that discarding individual lines of these k-space lines has no major impact.

If measurement data MD has been acquired, e.g. in an accelerated, and consequently undersampled manner (block 100), from which image data BD is to be reconstructed using coil sensitivity data, a loaded set SD of data acquired by means of the coil may in this case also have been determined on the basis of the acquired undersampled measurement data MD. In particular, measurement data MD measured by undersampling for an imaging process can be cropped to its central region in the k-space and this central part MDc of the measurement data MD can be loaded as the set SD of measured data.

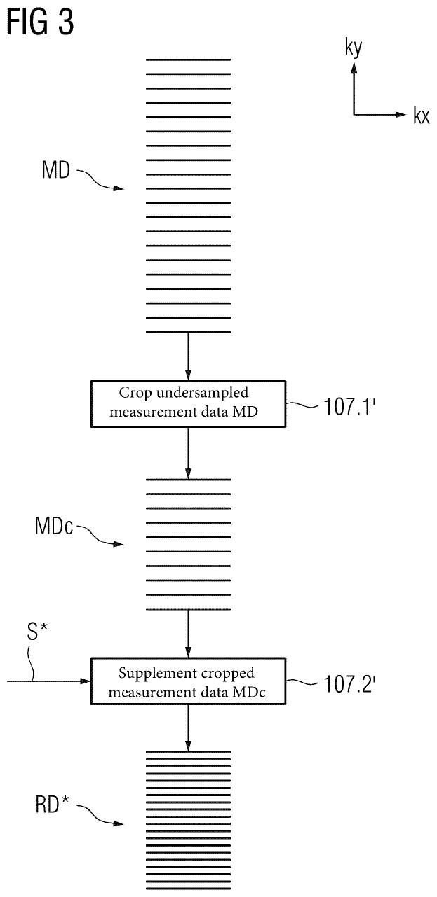

FIG. 3 illustrates a schematic diagram of an example further workflow for determining reconstructed reference data RD* according to the disclosure.

In the case shown here, measurement data MD acquired in an accelerated manner using a parallel acquisition technique, and consequently undersampled, is cropped to its central region (block 107.1′), with the result that only the central k-space lines in the k-space can be loaded as data MDc.

A set of cropped measurement data MDc loaded as a set SD of data acquired by means of the coil can be supplemented using the associated supplementary kernel S* to produce reconstructed reference data RD* that is complete according to Nyquist (block 107.2′), for example in accordance with a GRAPPA technique.

On the basis of the reconstructed reference data RD*, coil sensitivity data SM of the coil is determined (block 109) which can be used for a reconstruction of image data BD from measurement data MD (block 110), e.g. in the course of a CS method, a parallel acquisition method, or as part of a trained reconstruction function. The coil sensitivity data SM can be determined on the basis of the reconstructed reference data, e.g. with the aid of an ESPIRIT method, such as is described e.g. in Uecker et al. “ESPIRIT—An Eigenvalue Approach to Autocalibrating Parallel MRI: Where SENSE Meets GRAPPA”, Magn. Reson. Med. 71: pp. 990 1001, 2014.

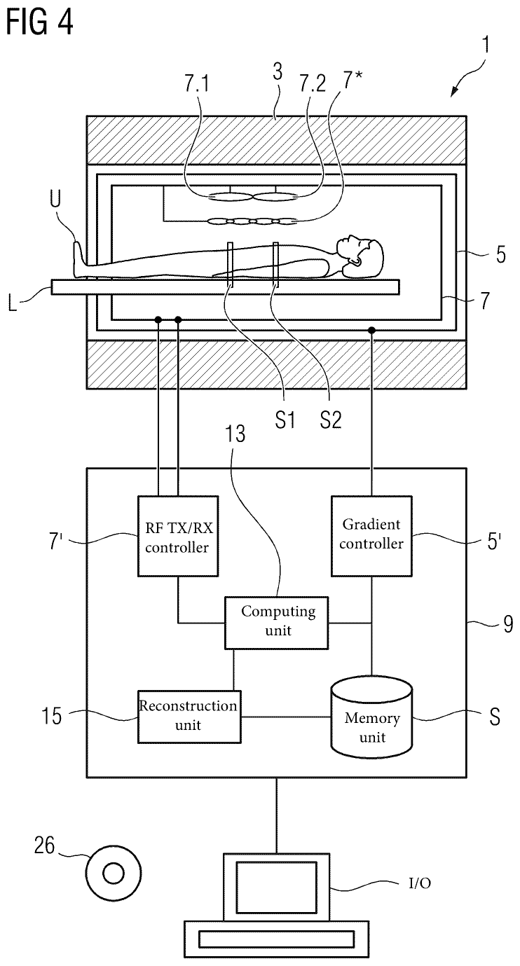

FIG. 4 illustrates a schematic view of an example magnetic resonance system 1 according to the disclosure. The magnetic resonance system comprises a magnet unit 3 (also referred to herein as a main magnet) for generating the basic magnetic field, a gradient unit 5 (also referred to herein as a gradient circuitry or gradient coils) for generating the gradient fields, a radiofrequency (RF) unit 7 (also referred to herein as an RF transmitter, receiver, or transceiver) for transmitting and/or for receiving radiofrequency signals, and a control device 9 (also referred to herein as a controller) embodied for performing any of the methods according to the disclosure.

These subsidiary units of the magnetic resonance system 1 are depicted in a roughly schematic view in FIG. 4. The radiofrequency unit 7 may comprise a plurality of subunits and, for example, comprise any suitable number of coils. As one example, the radiofrequency unit 7 may comprise a body coil that is permanently integrated in the magnetic resonance system 1, and once may for example comprise two antenna elements 7.1 and 7.2. The radiofrequency unit 7 may additionally comprise one or more different local coils 7*, which may be embodied either only for transmitting radiofrequency signals or only for receiving the triggered radiofrequency signals or for both, and for their part may comprise a number of antenna elements and associated coil channels.

In order to examine an examination subject U, for example a patient or also a phantom, the examination subject can be introduced on a couch L into the measurement volume of the magnetic resonance system 1. The slices S1 or S2 represent exemplary target volumes of the examination subject from which echo signals can be acquired and recorded as measurement data.

The control device 9 serves for controlling the magnetic resonance system 1 and can for instance control the gradient unit 5 by means of a gradient controller 5′ and the radiofrequency unit 7 by means of a radiofrequency transmit/receive controller 7′. In this case, the radiofrequency unit 7 may comprise a number of channels on which signals can be sent or received.

The radiofrequency unit 7 is responsible, together with its radiofrequency transmit/receive controller 7′, for generating and broadcasting (transmitting) an alternating radiofrequency field to manipulate the spins in a region of the examination subject U that is to be manipulated (for example in slices S that are to be measured). In the process the center frequency of the alternating radiofrequency field, also referred to as the B1 field, is usually adjusted as far as possible so that it lies close to the resonance frequency of the spins that are to be manipulated. Deviations of the center frequency from the resonance frequency are referred to as off-resonance. In order to generate the B1 field, currents controlled in the radiofrequency unit 7 by means of the radiofrequency transmit/receive controller 7′ are applied to the RF coils.

The control device 9 additionally comprises a reconstruction unit 15 (also referred to herein as a reconstruction circuitry or a reconstructor) for determining reference data reconstructed according to the disclosure. Overall, the control device 9 is embodied to perform a method according to the disclosure.

A computing unit 13 (also referred to herein as processing circuitry or one or more processors) incorporated in the control device 9 is embodied to perform all the computational operations necessary for the required measurements and provisions. Interim results and results required for this or determined in the process can be stored in a memory unit S of the control device 9. The illustrated units are in this case not necessarily to be understood as physically separate units, but simply represent a subdivision into notional units, yet which can also be realized e.g. in fewer physical units or even in just one single physical unit.

Control commands can be directed to the magnetic resonance system, e.g. by a user, and/or results of the control device 9 such as e.g. image data may be displayed by way of an input/output device (I/O) of the magnetic resonance system 1.

A method described herein may also be present in the form of a computer program comprising commands which perform the described method on a control device 9. Similarly, a non-transitory computer-readable storage medium may be present comprising commands which, when executed by means of a control device 9 of a magnetic resonance system 1, cause said control device to perform the described method.

Independent of the grammatical term usage, individuals with male, female or other gender identities are included within the term.

The various components described herein may be referred to as “units.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units, as applicable and relevant, may alternatively be referred to herein as “circuitry,” “controllers,” “processors,” or “processing circuitry,” or alternatively as noted herein.

What is claimed is:

1. A method, comprising:
acquiring, via a coil comprising at least two antenna elements and one coil channel per antenna element, reference data of individual slices of an examination subject in accordance with a magnetic resonance (MR) examination,
wherein the acquired reference data fully samples k-space at least in a central region of k-space according to a Nyquist condition;
loading at least one acquired data set that is acquired via the coil, the at least one acquired data set being undersampled according to the Nyquist condition;
determining a supplementary kernel for the at least one acquired data set based upon the acquired reference data;
determining, at least in the central region of the k-space, reconstructed reference data from the at least one acquired data set using the determined supplementary kernel, the reconstructed reference data being fully sampled according to the Nyquist condition; and
determining coil sensitivity data of the coil based upon the reconstructed reference data.

2. The method as claimed in claim 1, further comprising:
generating, from acquired measurement data of the examination subject, reconstructed image data based upon the coil sensitivity data.

3. The method as claimed in claim 1, wherein the acquired data set samples the central region of the k-space.

4. The method as claimed in claim 1, wherein at least two acquired data sets are loaded as the at least one acquired data set, each being supplemented using a respective associated supplementary kernel to produce respective supplemented data sets that are fully sampled according to the Nyquist condition, and
wherein the reconstructed reference data is determined based upon the respective supplemented data sets.

5. The method as claimed in claim 4, wherein the determination of the reconstructed reference data comprises averaging the respective supplemented data sets.

6. The method as claimed in claim 1, wherein the at least one acquired data set is determined based upon the reference data.

7. The method as claimed in claim 6, further comprising:
subdividing the reference data into undersampled data sets, which are loaded as the at least one acquired data set.

8. The method as claimed in claim 6, wherein the reference data is acquired in k-space lines, and
wherein n sets of the at least one acquired data set are generated by assigning every nth k-space line to a respective acquired data set.

9. The method as claimed in claim 4, wherein determining the reconstructed reference data comprises discarding non-supplemented data in the respective supplemented data sets.

10. The method as claimed in claim 4, wherein determining the reconstructed reference data comprises comparing at least two of the respective supplemented data sets to identify and selectively discard contaminated parts of k-space of the respective supplemented data sets.

11. The method as claimed in claim 1, wherein the acquired data sets are determined based upon acquired measurement data from which image data is to be reconstructed.

12. The method as claimed in claim 11, wherein the acquired measurement data is measured by performing undersampling in accordance with an imaging process and cropping the acquired measurement data to a central region in k-space, which is then loaded as a measurement data set.

13. A magnetic resonance system, comprising:
a main magnet; and
a controller configured to:
acquire, via a coil comprising at least two antenna elements and one coil channel per antenna element, reference data of individual slices of an examination subject in accordance with a magnetic resonance (MR) examination,
wherein the acquired reference data fully samples k-space at least in a central region of k-space according to a Nyquist condition;
load at least one acquired data set that is acquired via the coil, the at least one acquired data set being undersampled according to the Nyquist condition;
determine a supplementary kernel for the at least one acquired data set based upon the acquired reference data;
determine, at least in the central region of the k-space, reconstructed reference data from the at least one acquired data set using the determined supplementary kernel, the reconstructed reference data being fully sampled according to the Nyquist condition; and
determine coil sensitivity data of the coil based upon the reconstructed reference data.

14. A non-transitory computer-readable storage medium having instructions stored thereon that, when executed by a controller of a magnetic resonance device, cause the magnetic resonance device to:
acquire, via a coil comprising at least two antenna elements and one coil channel per antenna element, reference data of individual slices of an examination subject in accordance with a magnetic resonance (MR) examination,
wherein the acquired reference data fully samples k-space at least in a central region of k-space according to a Nyquist condition;
load at least one acquired data set that is acquired via the coil, the at least one acquired data set being undersampled according to the Nyquist condition;
determine a supplementary kernel for the at least one acquired data set based upon the acquired reference data;
determine, at least in the central region of the k-space, reconstructed reference data from the at least one acquired data set using the determined supplementary kernel, the reconstructed reference data being fully sampled according to the Nyquist condition; and
determine coil sensitivity data of the coil based upon the reconstructed reference data.
